(19) United States
(12) Patent Application Publication
(10) Pub. No.: US 2022/0014189 A1
(43) Pub. Date: Jan. 13, 2022

(54) SYSTEM AND METHOD FOR WIRELESS RECEPTACLE CONTROL WITH SENSOR

(71) Applicant: Pass & Seymour, Inc., Syracuse, NY (US)

(72) Inventor: Joshua P. Haines, Marcellus, NY (US)

(73) Assignee: Pass & Seymour, Inc., Syracuse, NY (US)

(21) Appl. No.: 17/354,449

(22) Filed: Jun. 22, 2021

Related U.S. Application Data
(60) Provisional application No. 63/048,923, filed on Jul. 7, 2020.

(51) Int. Cl. H03K 17/94; G01J 1/42

(52) U.S. Cl. CPC H03K 17/941; G01J 1/4204

(57) ABSTRACT

A system for automatically controlling at least one wirelessly controllable receptacle includes a photocell assembly comprising a photocell and photocell controller configured to detect a level of ambient light and to vary a light detection signal to have a first value when the level of ambient light is below a threshold and a second value when the level of ambient light is above the threshold; and a controller configured to receive the light detection signal and to wirelessly control at least one of a receptacle outlet or a switch, according to the light detection signal, wherein the controller is configured to wirelessly control the at least one receptacle or switch to turn ON in response to the first value of the light detection signal and to turn OFF in response to the second value of the light detection signal.

### CROSS REFERENCE TO RELATED APPLICATIONS

The present application claims priority to and the benefit of U.S. Provisional Patent Application No. 63/048,923, filed on Jul. 7, 2020, which is hereby incorporated by reference herein in its respective entirety.

### FIELD OF INVENTION

This application generally relates to a system for automatically controlling plugload receptacles or switches in accordance with ambient light.

### BACKGROUND

In a retail environment, and particularly in an electronics retail environment, multiple electronic devices are usually on display in a manner that consumes power. These electronic devices might include, for example, televisions, computers, tablets, smart phones, headphones, etc., which are or mounted to the wall or laid out on tables for a consumer to view or use before purchasing. At the close of a business day, to avoid needlessly consuming power while the retail store is closed, these devices are typically turned off. Employees of these retail environments, however, can occasionally neglect to turn off such devices, incurring additional cost for the retailer. There exists, then, a need for a control system that can detect when the retail environment is closed and remove power from display devices to avoid needless power consumption.

### SUMMARY

The examples described in this disclosure can be combined in any technically possible way.

According to an aspect, a system for automatically controlling at least one wirelessly controllable receptacle, includes: a photocell assembly comprising a photocell and photocell controller configured to detect a level of ambient light and to vary a light detection signal to have a first value when the level of ambient light is below a threshold and a second value when the level of ambient light is above the threshold; and a controller configured to receive the light detection signal and to wirelessly control at least one of a receptacle outlet or a switch, according to the light detection signal, wherein the controller is configured to wirelessly control the at least one receptacle or switch to turn ON in response to the first value of the light detection signal and to turn OFF in response to the second value of the light detection signal.

In an example, the photocell assembly further comprises a switch, wherein the photocell controller is configured to place the switch in a first state when the level of ambient light falls below the threshold amount and in a second state when the level of ambient light rises above the threshold amount, wherein the light detection signal is varied between the first value and the second value according to whether the switch is in the first state or the second state.

In an example, the photocell assembly further comprises a pull-up resistor, wherein the light detection signal is varied according to whether the pull-up resistor is connected to ground, wherein the pull-up resistor is not connected to ground when the switch is in the first state, such that the light detection signal is high, wherein the pull-up resistor is connected to ground when the switch is in the second state, such that the light detection signal is low.

In an example, the photocell assembly further comprises a pull-up resistor, wherein the light detection signal is varied according to whether the pull-up resistor is connected to ground, wherein the pull-up resistor is connected to ground when the switch is in the first state such that the light detection signal is low, wherein the pull-up resistor is not connected to ground when the switch is in the second state, such that the light detection signal is high.

In an example, the photocell controller comprises a microcontroller that is configured to output the light detection signal, wherein the microcontroller varies the light detection signal to have the first value when the level of ambient light is below the threshold and the second value when the level of ambient light is above the threshold.

In an example, the threshold is configured to be varied by a user.

In an example, the photocell assembly further comprises a second photocell and a second photocell controller.

In an example, the photocell, the photocell controller, and the switch are disposed in a housing.

In an example, the photocell controller comprises a microcontroller configured to generate the light detection signal.

In an example, the controller is configured to receive the light detection signal and to wirelessly control the at least one of a receptacle outlet or the switch according to a radio frequency signal or an infrared signal.

### BRIEF DESCRIPTION OF THE DRAWINGS

The present invention will be more fully understood and appreciated by reading the following Detailed Description in conjunction with the accompanying drawings. The accompanying drawings illustrate only typical embodiments of the disclosed subject matter and are therefore not to be considered limiting of its scope, for the disclosed subject matter may admit to other equally effective embodiments. Reference is now made briefly to the accompanying drawings, in which:

FIG. 1 is a schematic of a system for wirelessly controlling a plugload receptacle according to ambient light, according to an example.

FIG. 2 is a block diagram of a photocell device, according to an example.

FIG. 3 is a schematic of a system for wirelessly controlling a plugload receptacle according to ambient light, according to an example.

### DETAILED DESCRIPTION

Various examples described below provide a system and method for wirelessly controlling a plugload receptable in accordance with an intensity of ambient light.

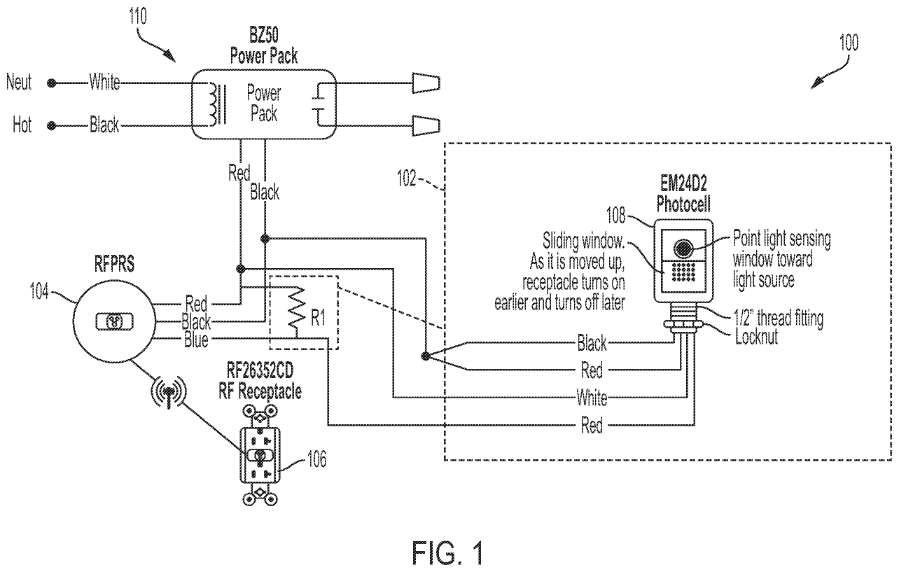

FIG. 1 depicts a system 100 for wirelessly controlling a plugload receptacle or switch in accordance with ambient light, as detected by a photocell. As shown in FIG. 1, the system 100 includes a photocell assembly 102 and a wireless controller 104 for controlling multiple plugload receptacles or switches, e.g., a wirelessly controllable plugload receptacle 106. Photocell assembly 102 (which, in this example, includes a photocell device 108 and resistor R1) detects a level of ambient light and varies a light detection signal to have a first value when the level of ambient light is below a threshold and a second value when the level of ambient light is above the threshold. The wireless controller 104 sends a ON signal or an OFF signal to at least one wirelessly controllable plugload receptacle 106 or to a switch (or some combination of wirelessly controllable plugload receptacles and switches) according to the value of the light detection signal. In an example, wirelessly controllable plugload receptacle 106 supplies power to one or more electronic devices, such as televisions or computers in a retail environment; although, it is conceivable that system 100 could be used outside of a retail environment and could be used power other sorts of devices. Power pack 110, in this example, provides power to photocell assembly 102 and to wireless controller 104 by converting a mains AC signal to a DC voltage (e.g., 24 VDC).

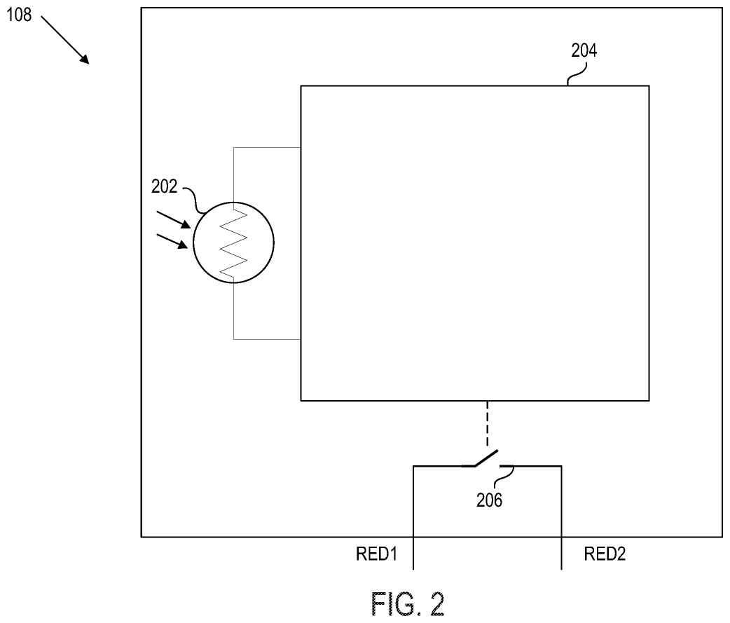

As mentioned above, photocell assembly 102 comprises a photocell device 108 and resistor R1. Photocell device 108, in this example, is an EM24D2 photocell device, offered by Pass & Seymour, which is a low-voltage photocell device. FIG. 2 depicts a simplified block diagram of photocell device 108 for the purposes of illustrating its operation in response to detecting an ambient light signal. Photocell device 108 includes a photocell 202 and a control circuit 204 (alternatively referred to herein as a “photocell controller”) which changes the state of relay switch 206 according to the behavior of photocell 202 in response to the ambient light. For the purposes of this disclosure, a photocell is a cell, such as a photovoltaic cell or photoconductive cell, that changes its electrical properties (e.g., resistance) in response to incident light. In operation, control circuit 204 closes relay switch 206, connecting the two red wires of photocell device 108, when the ambient light (as measured by the light incident on photocell 202) falls below the threshold, and opens the relay switch 206, disconnecting the red wires, when the ambient light rises above the threshold. Control circuit 204 can be implemented by a microcontroller, an ASIC, FPGA, or any other suitable circuit for controlling relay switch 206 in response to the state of photocell 202. Returning to FIG. 1, resistor R1 functions as a pull-up resistor: when the ambient light exceeds the threshold, resistor R1 is not connected to ground and thus a HIGH signal is received at wireless controller 104; whereas, when the ambient light falls below the threshold, the connected red wires tie the blue input wire of wireless controller 104 to ground, the voltage is dropped across resistor R1 and a LOW signal is received at wireless controller 104. Thus, photocell assembly 102 varies the light detection signal between a HIGH and a LOW value according to whether the ambient is above or below the threshold.

Stated differently, in operation, photocell device 108 opens a switch between red wires connected to photocell device 108 when the detected light is below a threshold value and closes the switch between the red wires when the detected light is above a threshold value. The red wire is tied to ground (black wire) or logic LOW.

| | Optocell Switch | Red 1 (tied to gnd) | Red2 |
|---|---|---|---|
| Light above threshold | Closed | 0 V | 0 V |
| Light below threshold | Open | 0 V | Open |

In the same or different examples, photocell assembly 102 need not include a photocell device 108 that houses both a photocell and a photocell controller; instead, the photocell (e.g., photocell 202) and photocell controller (e.g., photocell controller 204) can be implemented independently, outside of a dedicated housing.

In operation, the wireless controller 104 receives an input from the photocell and, based at least in part on that input, wirelessly controls the plug load receptacles and/or switches to turn off any connected load once the lights in the environment are turned OFF. Thus, in the example of FIG. 1, once the photocell detects that the lights in the environment (e.g., the retail store) are turned OFF, the wireless controller sends a wireless command to the plug load receptacles and/or switches to turn OFF the connected devices, that is, to cease providing power to the receptacles of the plugload receptacles or to turn the switches OFF. If screens or other devices are connected to the wirelessly controlled plug loads or switches, those screens and devices will be turned OFF automatically once the lights in the store turned OFF.

Wireless controller 104 can comprise an RFPRS Plug Load RF Signal Pack offered by Pass & Seymour; however, any wireless controller that can communicate with the photocell assembly, and, based at least in part on its input from the photocell assembly 102, wirelessly control one or more switches or plug load receptacles, can be used. The plug load receptacle can be, for example, an RF26352CD receptacle offered by Pass & Seymour; however, it should be understood that any suitable plug load receptacle 106 or wireless switch that can be controlled by the wireless controller 104 can be used. FIG. 1 further depicts that the photocell assembly 102 and wireless controller 104 are powered by a BZ50 Power Pack, offered by Pass & Seymour, although any suitable power source can be used.

While wireless controller 104 is shown to communicate with the wireless plugload receptacles 106 and switches via a radio frequency control signal (using a protocol such as a WiFi, Bluetooth, Zigbee, etc.), in alternative examples, other suitable wireless mediums, such as infrared, can be used. Wireless control is employed to avoid wires hanging from the ceiling, where the photocell and wireless controller are typically mounted.

In this example, the wireless controller enables the switch or plugload receptacle (ON) when the wireless controller 104 receives a low voltage input on the blue wire (control input). Conversely, the wireless controller 104 disables the switch or plugload receptacle (OFF) when the wireless controller sees a high voltage (e.g., +24V) on the blue wire (control input). This operation is depicted in Table 2, below.

| Wireless Controller Control | PlugLoad Receptacle/Switch |
|---|---|
| 0 V | Load ON |
| 24 V | Load OFF |

Thus, because photocell device closes the switch when it detects light above a certain threshold, a pullup resistor, R1, is required to invert the control input to the wireless controller. More specifically, as described above, when light is detected above the threshold, the switch will close, connecting one side of resistor R1 to ground. When this happens, the 24 VDC input will drop across R1, and thus the control input of the wireless controller 104 sees 0V (LOW). Conversely, when light above threshold is not detected, the photocell device 108 will open the switch. As a result, no current will flow through resistor R1 and the wireless controller will receive a high input (+24V).

In this example, the 24K value was chosen so that 1 mA flows through the resistor when ambient light is high (e.g., daytime). This current is appropriate because it is well within the powerpack 24V power supply ampacity and the resistor's power rating is quite safe at ¼ W which is a standard resistor power rating. It should however be understood that different resistor values can be selected as appropriate.

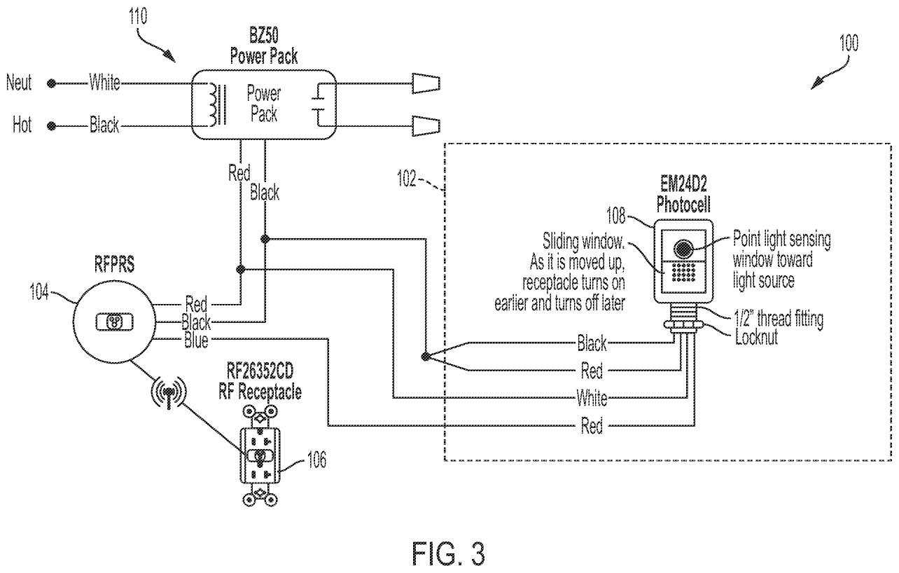

In an alternative example shown in FIG. 3, photocell controller 204 can be configured to close the relay switch when the ambient light rises above the threshold and to open the relay switch when the ambient falls below the threshold. In yet another alternative example, wireless controller 104 can enable the plugload receptacle 106 or switch when it receives a HIGH voltage. (This example would likewise adopt the configuration of FIG. 3.) These examples each obviate the need for pull-up resistor R1.

Furthermore, in an alternative example, the photocell controller 204 can directly output a HIGH or LOW signal, rather than only operating to close or open a relay, depending on how the relay switch is attached. For example, the photocell controller 204 can include a microcontroller programmed to read an output from the photocell and to output the light detection signal (e.g., having a HIGH or LOW value) to wireless controller 104. In this example, the light detection signal is generated by the microcontroller of photocell controller 204, rather than connecting an outside source of power to the wireless controller 104 through a relay.

In alternative examples, rather than using a photocell, other types of sensors can be employed. For example, various alternative sensors that detect occupancy can used, such as infrared sensors, sound sensors, or door switches. In one example, wireless controller 104 can send the OFF signal to the wirelessly controllable switches or plugload receptacles if a sound sensor, monitoring the ambient sound within the environment, detects that sound has dropped below a predetermined decibel level or drops below a predetermined decibel level for a certain amount of time. Similarly, wireless controller 104 can send the OFF signal if an infrared sensor detects the absent of infrared signals within the environment for a predetermined period of time. Likewise, wireless controller 104 can send the OFF signal if a door switch does not detect that the door has been used for predetermined period of time.

Alternatively, sensors that detect inoccupancy can be used to identify when the retail environment or other space is no longer occupied. For example, sensors that detect in-store humidity or high total organic air levels can be used to detect when the air within the store is not being refreshed by the HVAC system. Such a detection can indicate that store is not occupied by any customers or employees and can thus be used to trigger the OFF signal from wireless controller 104.

Furthermore, instead of a resistor, multiple connected photocells can be employed. The expected behavior of the multiple photocell circuit is described below in table 3.

| Photocell 1 | Photocell 2 | PlugLoad Receptacle/Switch |
|---|---|---|
| Day | Day | Load On |
| Day | Night | Load On |
| Night | Day | Load On |
| Night | Night | Load Off |

All references, including publications, patent applications, and patents, cited herein are hereby incorporated by reference to the same extent as if each reference were individually and specifically indicated to be incorporated by reference and were set forth in its entirety herein.

All definitions, as defined and used herein, should be understood to control over dictionary definitions, definitions in documents incorporated by reference, and/or ordinary meanings of the defined terms.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if not directly attached to where there is something intervening.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

1. A system for automatically controlling at least one wirelessly controllable receptacle, comprising:
a photocell assembly comprising a photocell and photocell controller configured to detect a level of ambient light and to vary a light detection signal to have a first value when the level of ambient light is below a threshold and a second value when the level of ambient light is above the threshold; and
a controller configured to receive the light detection signal and to wirelessly control at least one of a receptacle outlet or a switch, according to the light detection signal, wherein the controller is configured to wirelessly control the at least one receptacle or switch to turn ON in response to the first value of the light detection signal and to turn OFF in response to the second value of the light detection signal.

2. The system of claim 1, wherein the photocell assembly further comprises a switch, wherein the photocell controller is configured to place the switch in a first state when the level of ambient light falls below the threshold amount and in a second state when the level of ambient light rises above the threshold amount, wherein the light detection signal is varied between the first value and the second value according to whether the switch is in the first state or the second state.

3. The system of claim 2, wherein the photocell assembly further comprises a pull-up resistor, wherein the light detection signal is varied according to whether the pull-up resistor is connected to ground, wherein the pull-up resistor is not connected to ground when the switch is in the first state, such that the light detection signal is high, wherein the pull-up resistor is connected to ground when the switch is in the second state, such that the light detection signal is low.

4. The system of claim 2, wherein the photocell assembly further comprises a pull-up resistor, wherein the light detection signal is varied according to whether the pull-up resistor is connected to ground, wherein the pull-up resistor is connected to ground when the switch is in the first state such that the light detection signal is low, wherein the pull-up resistor is not connected to ground when the switch is in the second state, such that the light detection signal is high.

5. The system of claim 1, wherein the photocell controller comprises a microcontroller that is configured to output the light detection signal, wherein the microcontroller varies the light detection signal to have the first value when the level of ambient light is below the threshold and the second value when the level of ambient light is above the threshold.

6. The system of claim 1, wherein the threshold is configured to be varied by a user.

7. The system of claim 1, wherein the photocell assembly further comprises a second photocell and a second photocell controller.

8. The system of claim 1, wherein the photocell, the photocell controller, and the switch are disposed in a housing.

9. The system of claim 1, wherein the photocell controller comprises a microcontroller configured to generate the light detection signal.

10. The system of claim 1, wherein the controller is configured to receive the light detection signal and to wirelessly control the at least one of a receptacle outlet or the switch according to a radio frequency signal or an infrared signal.
